(19) United States
(12) Patent Application Publication
(10) Pub. No.: US 2025/0015527 A1
(43) Pub. Date: Jan. 9, 2025

(54) SMALL FORM FACTOR SHUNTED SOCKET PINS AND CONFIGURATION FOR IMPROVED SINGLE ENDED SIGNALING

(71) Applicant: Intel Corporation, Santa Clara, CA (US)

(72) Inventor: Landon HANKS, Milwaukie, OR (US)

(21) Appl. No.: 18/892,937

(22) Filed: Sep. 23, 2024

(51) Int. Cl. H01R 13/24; G06F 1/18; H01R 12/71; H05K 3/34; H05K 7/10

(52) U.S. Cl. CPC H01R 13/2442; G06F 1/185; H01R 12/714; H05K 3/3478; H05K 7/1069; H05K 2203/041

(57) ABSTRACT

Small form factor shunted socket pins and configurations for improved single ended signaling. The shunted socket pin includes a cantilevered spring member coupled to an upper portion of a body having a lower lever directed in a first direction coupled to an upper lever directed in a second direction to form a nose, the cantilevered spring member folding back on itself, and a shunting lever, coupled to the upper portion of the body. The body is coupled to a base, such as a solder ball. When the socket pin is compressed, a portion of the shunting lever is in contact with a portion of the cantilevered member, creating a shunted (and shorter) electrical path between contact pads on a socketed IC, SoC, or SoP and a contact pad or via on a PCB to which the solder ball is coupled.

### BACKGROUND INFORMATION

A Land Grid Array (LGA) is a type of surface-mount packaging for integrated circuits (ICs) that is notable for having the pins on the socket (when a socket is used)—as opposed to pins on the integrated circuit, known as a pin grid array (PGA). An LGA can be electrically connected to a printed circuit board (PCB) either by the use of a socket or by soldering directly to the board. LGAs may also be called LGA sockets when designed to be used with socketed ICs or socketed packages, such as microprocessors, System on Chip (SoCs), and System on Package (SoPs), and high-speed memory.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein like reference numerals refer to like parts throughout the various views unless otherwise specified:

FIGS. 1a, 1b, 1c, 1d, 1e, and 1f respectively show isometric, side, front, back, top, and bottom views of a socket pin that is currently used in some LGA sockets;

FIGS. 2a, 2b, 2c, 2d, 2e, and 2f respectively show isometric, side, front, back, top, and bottom views of a socket pin 200, according to one embodiment.

FIGS. 3a, 3b, and 3c respectively show an uncompressed socket pin configuration, a compressed socket pin configuration, and an overlapped combination of the uncompressed and compressed configurations, according to one embodiment;

FIGS. 4a and 4b respectively show height and length dimensions of a conventional socket pin;

FIGS. 4c and 4d respectively show height and length dimensions of a socket pin according to one embodiment;

FIG. 5a shows a socket pin configuration using the socket pin of FIGS 1a, 1b, 1c, 1d, 1e, and 1f;

FIG. 5b shows a socket pin configuration using the socket pin of FIGS. 2a, 2b, 2c, 2d, 2e, and 2f;

FIGS. 6a and 6b respectively show topside and underside isometric views of an LGA socket in which socket pins are installed, according to one embodiment;

FIG. 6c shows a cross-section view of the LGA socket of FIGS. 6a and 6b;

FIG. 7 is a graph illustrating a comparison for power sum far end cross talk (FEXT) for a current socket pin and a novel socket pin in accordance with embodiments herein;

FIG. 8 is a graph illustrating a comparison for power sum near end cross talk (NEXT) for a current socket pin and a novel socket pin in accordance with embodiments herein;

FIG. 9 is a graph illustrating a Time Domain Reflectometry (TDR) impedance performance comparison between the current socket pin and the novel socket pin; and

FIG. 10 is a diagram of a compute platform or server that may be implemented with aspects of the embodiments described and illustrated herein.

### DETAILED DESCRIPTION

Embodiments of small form factor shunted socket pins and configurations for improved single ended signaling are described herein. In the following description, numerous specific details are set forth to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

For clarity, individual components in the Figures herein may also be referred to by their labels in the Figures, rather than by a particular reference number. Additionally, reference numbers referring to a particular type of component (as opposed to a particular component) may be shown with a reference number followed by “(typ)” meaning “typical.” It will be understood that the configuration of these components will be typical of similar components that may exist but are not shown in the drawing Figures for simplicity and clarity or otherwise similar components that are not labeled with separate reference numbers. Conversely, “(typ)” is not to be construed as meaning the component, element, etc. is typically used for its disclosed function, implement, purpose, etc.

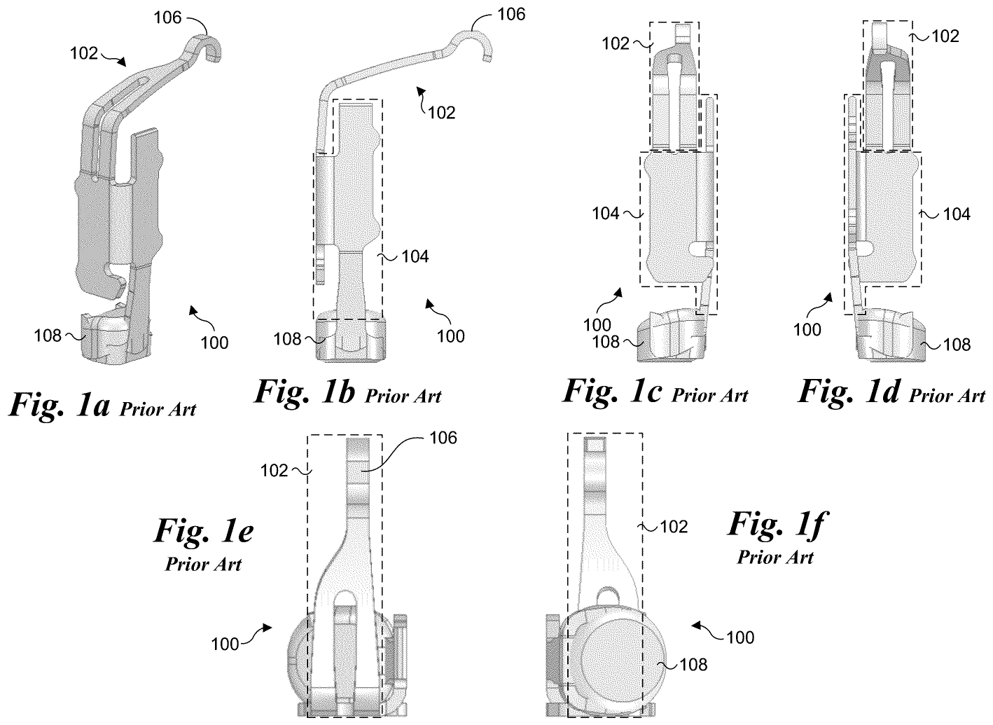

FIGS. 1a, 1b, 1c, 1d, 1e, and 1f respectively show isometric, side, front, back, top, and bottom views of a socket pin 100 that is currently used in some LGA sockets. Socket pin 100 includes a cantilevered contact 102 that extends upward and forward from a body 104 and operates like a cantilevered leaf spring with a floating end. The floating end includes an arch-shaped contact area 106 that is placed in contact with a contact pad on the underside of the socketed IC or package, such as a processor, SoC, SoP, etc. When the socketed IC or package is installed in the LGA socket, contact area 106 is pushed downward. The places the contact pad in contact with contact area 106 of socket pin 100. This creates an electrical pathway from contact area 106 through cantilevered contact 102, body 104 to a base 108. The base includes a solder ball that is coupled to a contact pad or other type of mating contact on a printed circuit board (PCB).

Generally, for a given LGA socket, all the pins will or may have the same physical structure, observing there may be LGA sockets with more than one type of pin. For modern processors, SoCs, and SoPs, the number of pins is on the order of a thousand, with higher numbers expected in the future. This will require LGA socket pins with higher densities.

Meanwhile, the bandwidth of input/output (I/O) signals continues to increase. Such I/O signals include single ended memory channel signals, with single ended signaling striving for higher speeds above 9200 MT/s for DDR5/6 (Double Data Rate 5^{th} and 6^{th} generation) and beyond, platform interconnects require tighter signal integrity constraints.

In accordance with aspects of the embodiments disclosed herein, novel socket pin and LGA sockets are provided that support both increased density and improved signal integrity over existing LGA sockets and pins. The novel socket pins also provide improved signal integrity and performance. For example, the novel socket pins employ a pin height and shape that contribute to signal margin improvements by shunting to reduce signal path, near and far end cross talk reduction by geometric design, near and far end cross talk by pin configuration, and impedance balancing by the pin shape.

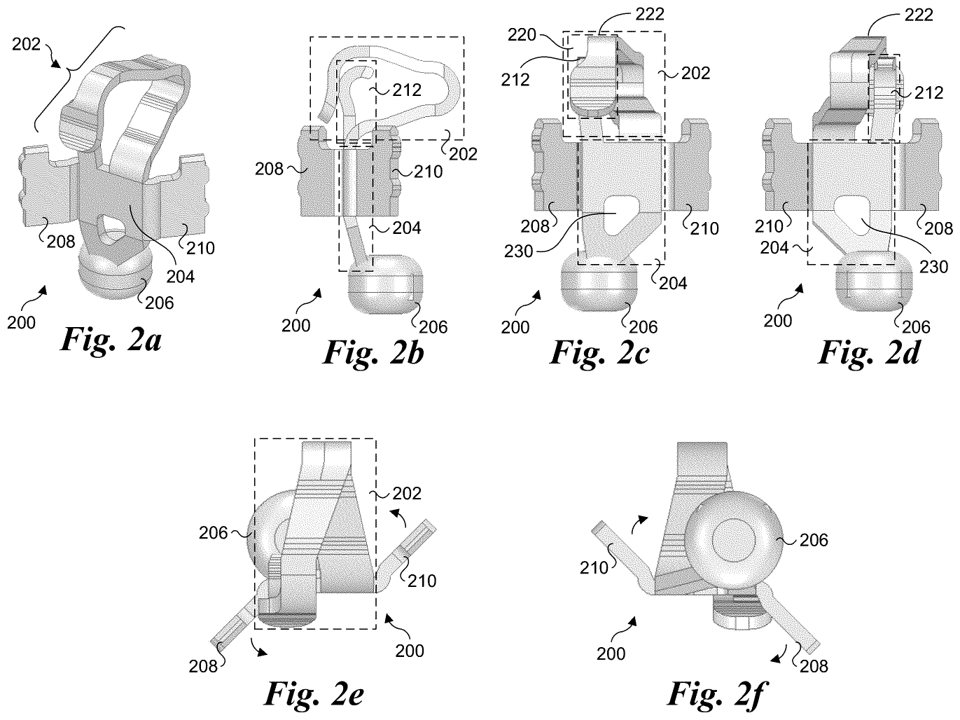

FIGS. 2a, 2b, 2c, 2d, 2e, and 2f respectively show isometric, side, front, back, top, and bottom views of a socket pin 200, according to one embodiment. Socket pin 200 includes a cantilevered spring member 202 coupled to a body 204 that is mounted to a base 206. In one embodiment, base 206 comprises a solder ball. Tabs 208 and 210 are attached to body 204. Socket pin 200 further includes a shunting lever 212.

As shown in FIGS. 2e and 2f, tabs 208 and 210 are angled relative to body 204 when viewed from top and bottom views. It is noted that these views represent the configuration of socket pin 200 before it is installed in a housing slot in a connector housing. Also, before pins are installed, arm 208 is bent downward and arm 210 is bent upward when viewed from the top (FIG. 2e). The tabs serve a dual purpose. First, they are used to secure the socket pin within the connector housing, and second, they provide a signal shielding function.

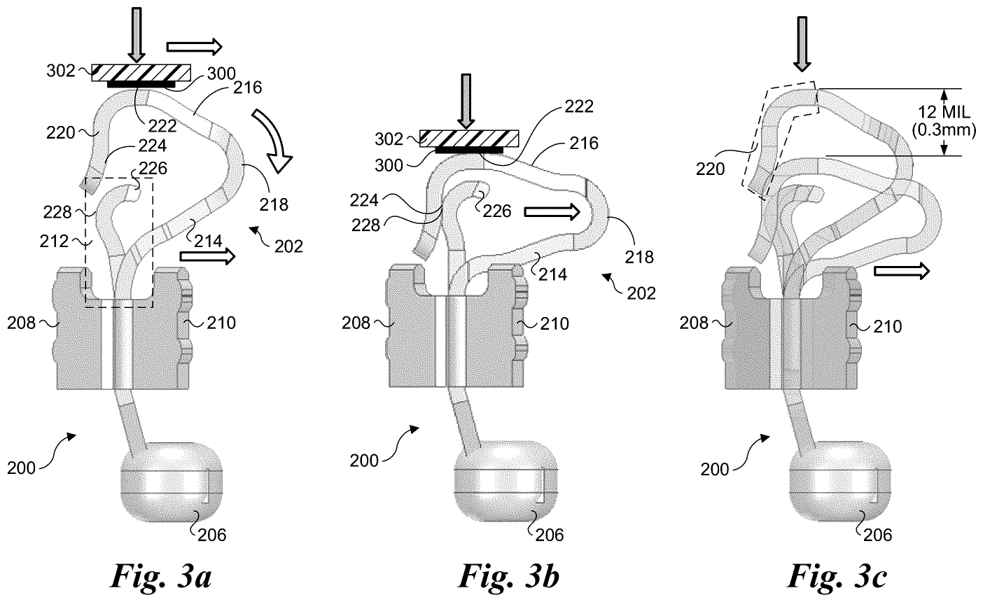

Further details of socket pin 200 are shown in FIGS. 3a, 3b, and 3c. As shown in the uncompressed configuration of FIG. 3a, cantilevered spring member 202 includes a lower lever 214 coupled to an upper lever 216 via a nose 218. A tail 220 is coupled to upper lever 216, with the overall configuration of cantilevered spring member 202 folding back on itself. Cantilevered spring member 202 further includes a contact area 224 proximate to the apex of the structure and an inner contact surface 224 on the inside surface of tail 220.

When viewed from the side, shunting lever 212 begins with a slight offset from its connection with an upper portion of body 204 and arcs back to form a hook-like shape with a free end 226. The left-most portion (approximately) of the shunting lever 212 comprises a contact surface 228.

Returning to FIGS. 2c and 2d, these figures show further details of body 204, cantilevered spring member 202, and shunting lever 212. The front and back views here are from a viewpoint that is substantially perpendicular to the planar front face and back face of body 204. As illustrated, the shape of body 204 is offset relative to base 206. Body 204 further includes an optional cutout 230.

As shown in FIG. 2c, the fixed ends of cantilevered spring member 202 and shunting lever 212 are coupled to an upper portion of body 204 on opposing sides of the body. In this example, cantilevered spring member 202 is shaped such that tail 220 is disposed above shunting lever 212. Additionally, contact surface 222 is generally vertically aligned with and disposed above base 206 in the front and back views shown in FIGS. 2c and 2d.

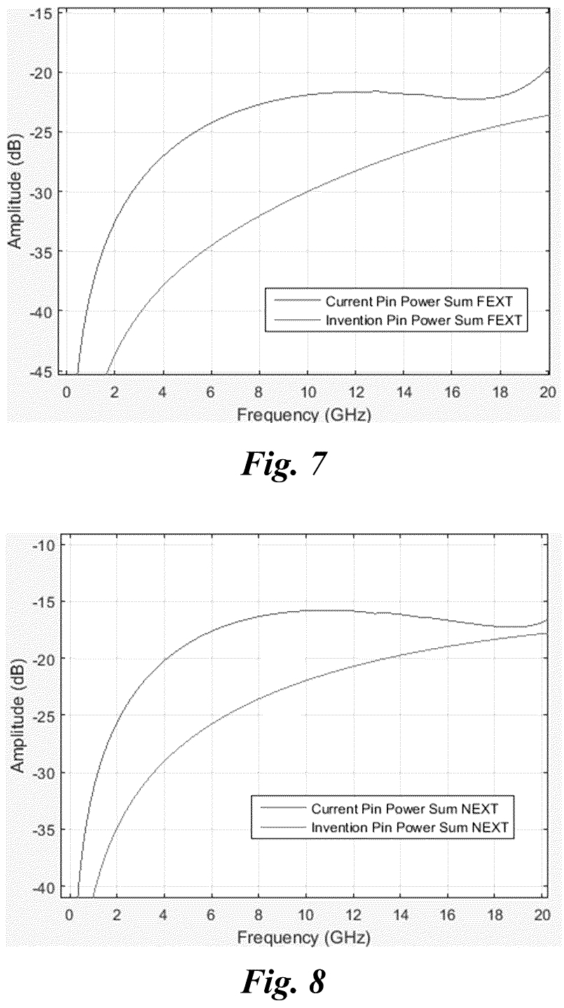

Returning to FIGS. 3a, 3b, and 3c, when a socketed IC or package is installed in the LGA socket, contact pads on the underside of the IC or package are aligned with respective contact surfaces 222 on socket pin 200. This is illustrated in FIGS. 3a and 3b, which show a contact 300 disposed on the underside of a substrate 302, which represents an socketed IC or package. As substrate 302 is pushed down, it causes cantilevered spring member 202 to flex, as shown in FIGS. 3b and 3c. The motion of contact surface 222 is generally vertical, while nose 218 is pushed forward, as shown in FIG. 3c. In the illustrated embodiment, the vertical movement is 12 MIL (thousands of an inch) (0.3 mm). This flexing motion also results in inner contact surface 224 coming into contact with contact surface 228 on shunting lever 212, which causes the shunting lever to bend forward (toward the right in FIGS. 3b and 3c). This creates a shortened electrical path between contact pad 300 and base (solder ball) 206 when compared with the conventional socket pin 100 illustrated and discussed above. Further performance comparison data are presented in graphs in FIGS. 7-9 below.

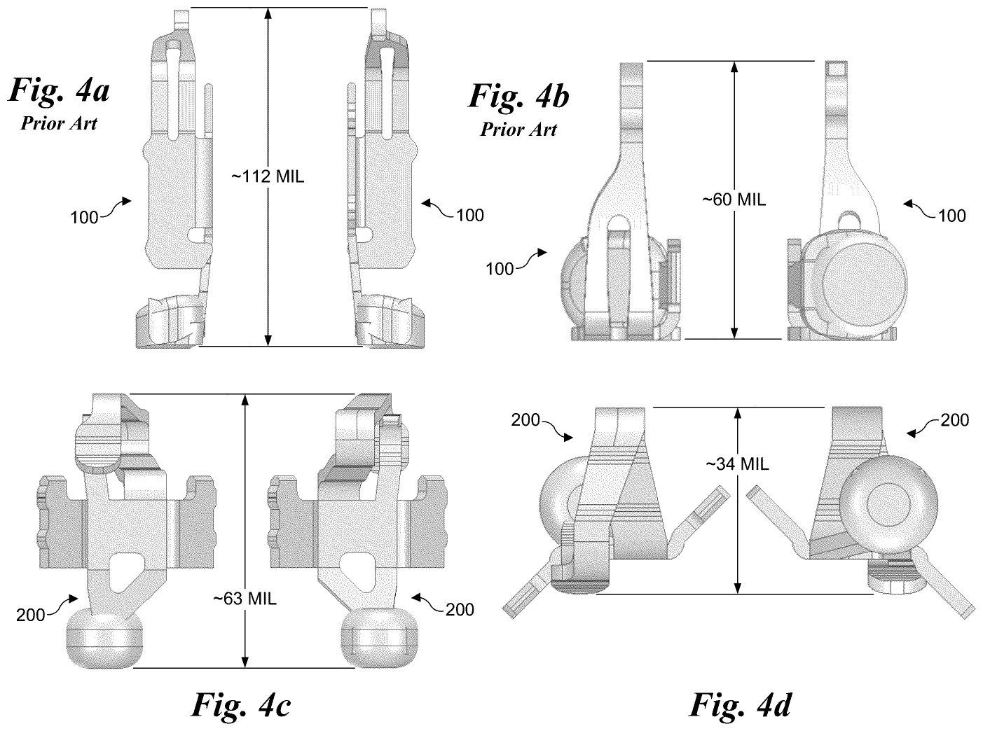

FIGS. 4a, 4b, 4c, and 4d illustrate a size comparison between conventional socket pin 100 and new socket pin 200, according to one embodiment. As shown in FIGS. 4a and 4c, the height of socket pin 200 is reduced from approximately 112 MIL to approximately 63 MIL, while the length (in the horizontal plane) is reduced from approximately 60 MIL to approximately 34 MIL.

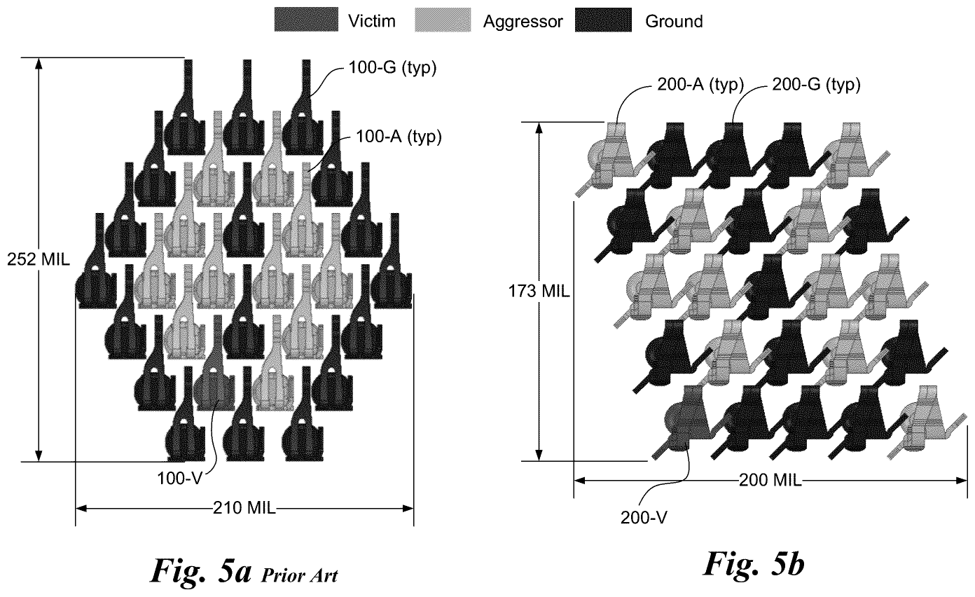

FIGS. 5a and 5b show a comparison between arrangements of socket pins under a current LGA socket and a novel LGA socket using embodiments of the socket pins described and illustrated herein. It is noted FIGS. 5a and 5b only depict a small fraction of the socket pins that would be present on an actual LGA socket, which may include upward of a thousand or more socket pins.

Generally, the illustrated socket pins are used to support the same signal functionality for, e.g., a memory device, such as a DDR5 or DDR6 DIMM. The “aggressor” pins are used for memory channel signals, with the “ground” socket pins are used for ground (GND) and the “victim” socket pins are for testing signal performance and integrity, as shown in the graphs of FIGS. 7-9 below. Other socket pins (not shown) could be used for any number of I/O′s including requisite signaling, power to the CPU, GPU I/O′s if on the SoC, etc.

As shown in FIG. 5a, the configuration includes 30 socket pins total including 11 aggressor pins 100-A, 18 ground socket pins 100-G, and one victim socket pin 100-V. By comparison, the configuration shown in FIG. 5b includes 11 aggressor pins 200-A, only 13 ground socket pins 200-G, and one victim socket pin 200-V. As further shown, the area occupied by the conventional socket pin arrangement in FIG. 5a is 210×252 MILs, while the area occupied by the novel socket pin arrangement in FIG. 5b is reduced to 200×173 MILs. As described an illustrated by the graphs below, part of the reason the novel socket pin arrangement can employ less ground socket pins are the improved signal performance provided by the novel socket pins in accordance with the embodiments described herein. A second aspect of the reduced area is the physical size of the novel socket pins is smaller than the conventional pins, as shown in FIGS. 4a and 4b above.

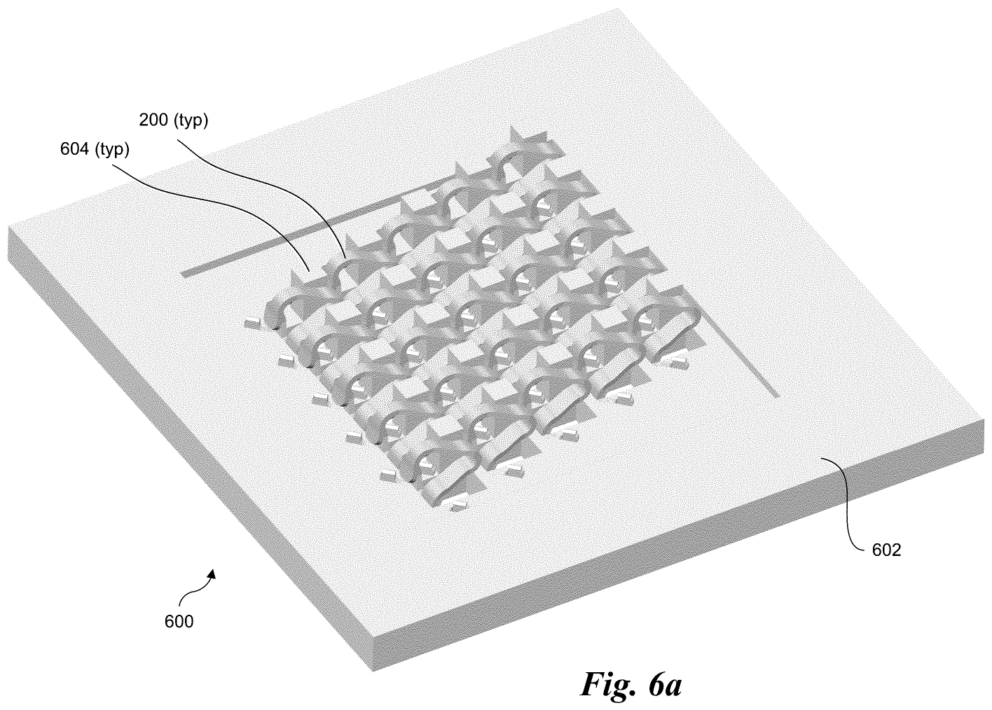

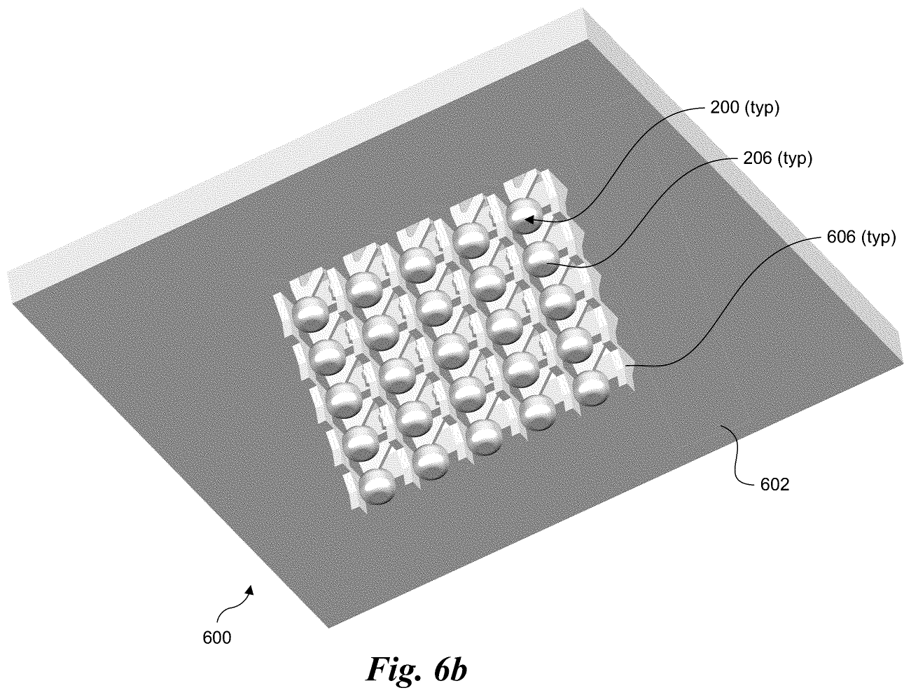

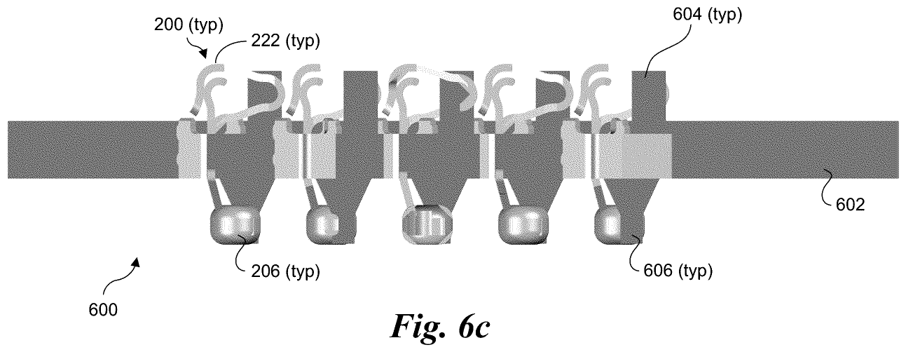

FIGS. 6a and 6b respectively show topside and underside isometric views of an LGA socket 600 in which socket pins 200 are installed, according to one embodiment. LGA socket 600 is a simplified representation of an LGA socket showing only a portion of the LGA socket for illustrative purposes. An LGA socket includes a housing 602 made of a suitable material, such as a plastic material or the like. As is known in the art, an LGA socket, in practice, comprises an assembly with multiple other components that are not shown in FIGS. 6a and 6b for simplicity and so as to not obscure the focus on the illustrated socket pins 200.

Each socket pin 200 will be installed in a respective slot or the like in housing 602 during a manufacturing operation using automated equipment. For ease of explanation, socket pins 200 are shown having the configuration illustrated in FIGS. 2a-2f which depicts arms 208 and 210 extending outward at an angle. As described above, before installation in its housing slot, arm 208 is folded downward while arm 210 is folded upward to secure the socket pin in the housing slot. A standoff 604 is disposed proximate to each socket pin. As further shown in the underside isometric view of FIG. 6b, the solder balls of the bases 206 of each socket pin 200 are exposed on the underside of the LGA connector. In addition, there is a standoff 606 disposed proximate to each solder ball.

FIG. 6c shows a cross-section view of LGA socket 600 that better illustrates the functions of standoffs 604 and 606. In this configuration, each socket pin 200 is in an uncompressed state, with the tops of the socket pins extending above the tops of standoffs 604. When the IC socket or SoC/SoP socket is installed, the contact area 222 of each socket pin will be pushed down until the apex of contact area 222 matches the top of the adjacent standoff 604. Also, the bottom of each standoff 606 is about the same as the bottom of the solder balls for bases 206.

FIGS. 7 and 8 respectively shows a graph illustrating power sum far end cross talk (FEXT) versus frequency and power sum near end cross talk (NEXT) for a current socket pin and the novel socket pin described and illustrated above. The plots are derived from models implementing the socket pin configuration shown in FIGS. 5a and 5b above and correspond to victim socket pins 100-V and 200-V, respectively. As shown in both graphs, the novel socket pin provides improved power sum FEXT and NEXT throughout the frequency range.

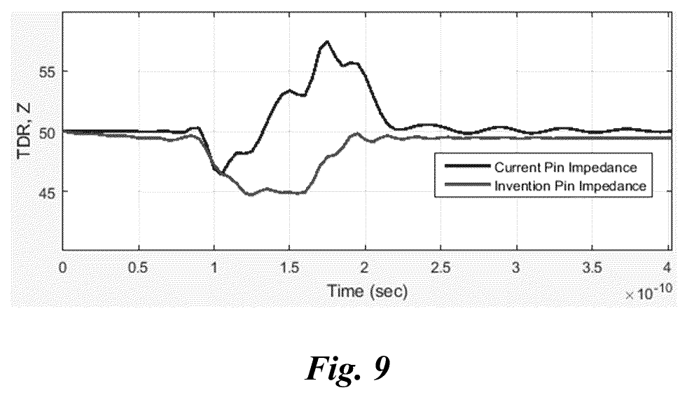

FIG. 9 shows a graph illustrating a Time Domain Reflectometry (TDR) impedance performance comparison between the conventional socket pin 100 and the novel socket pin 200. Again, the novel socket pin provides enhanced TDR impedance performance over the conventional socket pin. This results, in part, from the use of the shunted lever which provides a shunted (and shorter) electrical path between the pad on the underside of the socketed IC/SoC/SoP and the solder ball connection to the motherboard PCB.

### Example Compute Platform

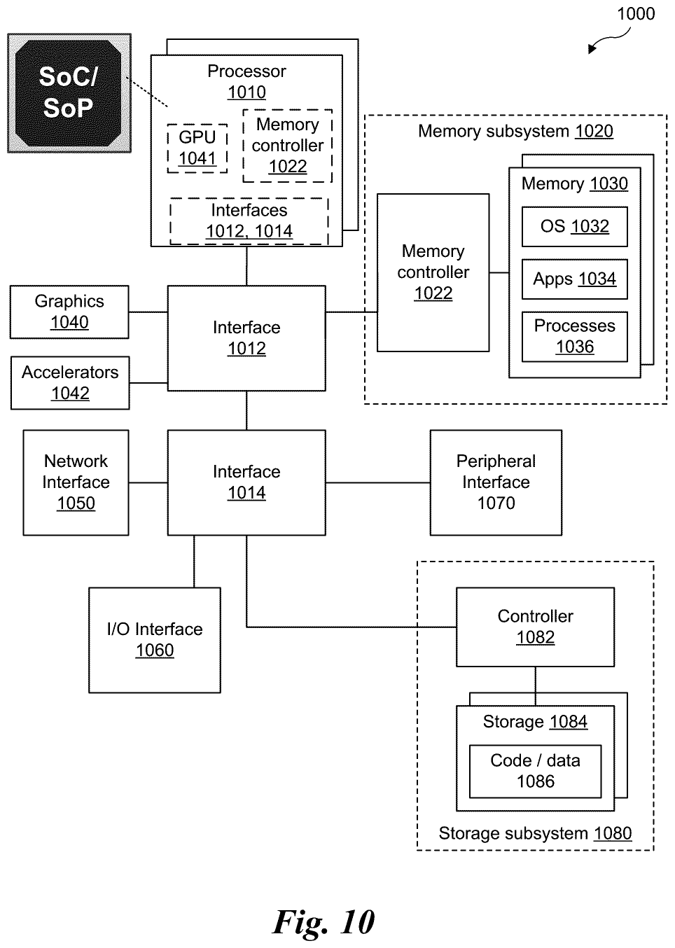

FIG. 10 depicts a compute platform 1000 in which aspects of the embodiments disclosed above may be implemented. Compute platform 1000 includes one or more processors 1010, which provides processing, operation management, and execution of instructions for compute platform 1000. Processor 1010 can include any type of microprocessor, central processing unit (CPU), graphics processing unit (GPU), processing core, multi-core processor or other processing hardware to provide processing for compute platform 1000, or a combination of processors. Processor 1010 controls the overall operation of compute platform 1000, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

In one example, compute platform 1000 includes interface 1012 coupled to processor 1010, which can represent a higher speed interface or a high throughput interface for system components that needs higher bandwidth connections, such as memory subsystem 1020 or optional graphics interface components 1040, or optional accelerators 1042. Interface 1012 represents an interface circuit, which can be a standalone component or integrated onto a processor die. Where present, graphics interface 1040 interfaces to graphics components for providing a visual display to a user of compute platform 1000. In one example, graphics interface 1040 can drive a high definition (HD) display that provides an output to a user. High definition can refer to a display having a pixel density of approximately 100 PPI (pixels per inch) or greater and can include formats such as full HD (e.g., 10100 p), retina displays, 4 K (ultra-high definition or UHD), or others. In one example, the display can include a touchscreen display. In one example, graphics interface 1040 generates a display based on data stored in memory 1030 or based on operations executed by processor 1010 or both. In one example, graphics interface 1040 generates a display based on data stored in memory 1030 or based on operations executed by processor 1010 or both.

In some embodiments, accelerators 1042 can be a fixed function offload engine that can be accessed or used by a processor 1010. For example, an accelerator among accelerators 1042 can provide data compression capability, cryptography services such as public key encryption (PKE), cipher, hash/authentication capabilities, decryption, or other capabilities or services. In some embodiments, in addition or alternatively, an accelerator among accelerators 1042 provides field select controller capabilities as described herein. In some cases, accelerators 1042 can be integrated into a CPU socket (e.g., a connector to a motherboard or circuit board that includes a CPU and provides an electrical interface with the CPU). For example, accelerators 1042 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs). Accelerators 1042 can provide multiple neural networks, CPUs, processor cores, general purpose graphics processing units, or graphics processing units can be made available for use by AI or ML models. For example, the AI model can use or include any or a combination of: a reinforcement learning scheme, Q-learning scheme, deep-Q learning, or Asynchronous Advantage Actor-Critic (A3C), combinatorial neural network, recurrent combinatorial neural network, or other AI or ML model. Multiple neural networks, processor cores, or graphics processing units can be made available for use by AI or ML models.

Memory subsystem 1020 represents the main memory of compute platform 1000 and provides storage for code to be executed by processor 1010, or data values to be used in executing a routine. Memory subsystem 1020 can include one or more memory devices 1030 such as read-only memory (ROM), flash memory, one or more varieties of random access memory (RAM) such as DRAM, or other memory devices, or a combination of such devices. Memory 1030 stores and hosts, among other things, operating system (OS) 1032 to provide a software platform for execution of instructions in compute platform 1000. Additionally, applications 1034 can execute on the software platform of OS 1032 from memory 1030. Applications 1034 represent programs that have their own operational logic to perform execution of one or more functions. Processes 1036 represent agents or routines that provide auxiliary functions to OS 1032 or one or more applications 1034 or a combination. OS 1032, applications 1034, and processes 1036 provide software logic to provide functions for compute platform 1000. In one example, memory subsystem 1020 includes memory controller 1022, which is a memory controller to generate and issue commands to memory 1030. It will be understood that memory controller 1022 could be a physical part of processor 1010 or a physical part of interface 1012. For example, memory controller 1022 can be an integrated memory controller, integrated onto a circuit with processor 1010.

While not specifically illustrated, it will be understood that compute platform 1000 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a Hyper Transport or industry standard architecture (ISA) bus, a small computer system interface (SCSI) bus, a universal serial bus (USB), or an Institute of Electrical and Electronics Engineers (IEEE) standard 1394 bus (Firewire).

In one example, compute platform 1000 includes interface 1014, which can be coupled to interface 1012. In one example, interface 1014 represents an interface circuit, which can include standalone components and integrated circuitry. In one example, multiple user interface components or peripheral components, or both, couple to interface 1014. Network interface 1050 provides compute platform 1000 the ability to communicate with remote devices (e.g., servers or other computing devices) over one or more networks. Network interface 1050 can include an Ethernet adapter, wireless interconnection components, cellular network interconnection components, USB (universal serial bus), or other wired or wireless standards-based or proprietary interfaces. Network interface 1050 can transmit data to a device that is in the same data center or rack or a remote device, which can include sending data stored in memory. Network interface 1050 can receive data from a remote device, which can include storing received data into memory. Various embodiments can be used in connection with network interface 1050, processor 1010, and memory subsystem 1020.

In one example, compute platform 1000 includes one or more I/O interface(s) 1060. I/O interface 1060 can include one or more interface components through which a user interacts with compute platform 1000 (e.g., audio, alphanumeric, tactile/touch, or other interfacing). Peripheral interface 1070 can include any hardware interface not specifically mentioned above. Peripherals refer generally to devices that connect dependently to compute platform 1000. A dependent connection is one where compute platform 1000 provides the software platform or hardware platform or both on which operation executes, and with which a user interacts.

In one example, compute platform 1000 includes storage subsystem 1080 to store data in a nonvolatile manner. In one example, in certain system implementations, at least certain components of storage 1080 can overlap with components of memory subsystem 1020. Storage subsystem 1080 includes storage device(s) 1084, which can be or include any conventional medium for storing large amounts of data in a nonvolatile manner, such as one or more magnetic, solid state, or optical based disks, or a combination. Storage 1084 holds code or instructions and data 1086 in a persistent state (i.e., the value is retained despite interruption of power to compute platform 1000). Storage 1084 can be generically considered to be a “memory,” although memory 1030 is typically the executing or operating memory to provide instructions to processor 1010. Whereas storage 1084 is nonvolatile, memory 1030 can include volatile memory (i.e., the value or state of the data is indeterminate if power is interrupted to compute platform 1000). In one example, storage subsystem 1080 includes controller 1082 to interface with storage 1084. In one example controller 1082 is a physical part of interface 1014 or processor 1010 or can include circuits or logic in both processor 1010 and interface 1014.

Volatile memory is memory whose state (and therefore the data stored in it) is indeterminate if power is interrupted to the device. Dynamic volatile memory requires refreshing the data stored in the device to maintain state. One example of dynamic volatile memory includes DRAM (Dynamic Random Access Memory), or some variant such as Synchronous DRAM (SDRAM). A memory subsystem as described herein may be compatible with a number of memory technologies, such as DDR3 (Double Data Rate version 3) JESD79-3F, originally published by JEDEC (Joint Electronic Device Engineering Council) in June 2007. DDR4 (DDR version 4), JESD209-4D, originally published in September 2012, DDR5 (DDR version 5), JESD79-5B, originally published in June 2021, DDR6 (DDR version 6), currently in discussion by JEDEC, LPDDR3 (Low Power DDR version 3, JESD209-3C, originally published in August 2015, LPDDR4 (LPDDR version 4, JESD209-4D, originally published in June 2021), LPDDR5 (LPDDR version 5, JESD209-5B, originally published in June 2021), WIO2 (Wide Input/Output version 2), JESD229-2, originally published in August 2014, HBM (High Bandwidth Memory, JESD235B, originally published in December 2018, HBM2 (HBM version 2, JESD235D, originally published in March 2021, HBM3 (HBM version 3, JESD238A originally published in January 2023) or HBM4 (HBM version 4), currently in discussion by JEDEC, or others or combinations of memory technologies, and technologies based on derivatives or extensions of such specifications. The JEDEC standards are available at www.jedec.org.

A non-volatile memory (NVM) device is a memory whose state is determinate even if power is interrupted to the device. In one embodiment, the NVM device can comprise a block addressable memory device, such as NAND technologies, or more specifically, multi-threshold level NAND flash memory (for example, Single-Level Cell (“SLC”), Multi-Level Cell (“MLC”), Quad-Level Cell (“QLC”), Tri-Level Cell (“TLC”), or some other NAND). A NVM device can also comprise a byte-addressable write-in-place three dimensional cross point memory device, or other byte addressable write-in-place NVM device (also referred to as persistent memory), such as single or multi-level Phase Change Memory (PCM) or phase change memory with a switch (PCMS), NVM devices that use chalcogenide phase change material (for example, chalcogenide glass), resistive memory including metal oxide base, oxygen vacancy base and Conductive Bridge Random Access Memory (CB-RAM), nanowire memory, ferroelectric random access memory (FeRAM, FRAM), magneto resistive random access memory (MRAM) that incorporates memristor technology, spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory.

A power source (not depicted) provides power to the components of compute platform 1000. More specifically, power source typically interfaces to one or multiple power supplies in compute platform 1000 to provide power to the components of compute platform 1000. In one example, the power supply includes an AC to DC (alternating current to direct current) adapter to plug into a wall outlet. Such AC power can be renewable energy (e.g., solar power) power source. In one example, power source includes a DC power source, such as an external AC to DC converter. In one example, power source or power supply includes wireless charging hardware to charge via proximity to a charging field. In one example, power source can include an internal battery, alternating current supply, motion-based power supply, solar power supply, or fuel cell source.

In an example, compute platform 1000 can be implemented using interconnected compute sleds of processors, memories, storages, network interfaces, and other components. High speed interconnects can be used such as: Ethernet (IEEE 802.3), remote direct memory access (RDMA), InfiniBand, Internet Wide Area RDMA Protocol (iWARP), quick UDP Internet Connections (QUIC), RDMA over Converged Ethernet (ROCE), Peripheral Component Interconnect express (PCIe), Intel® QuickPath Interconnect (QPI), Intel® Ultra Path Interconnect (UPI), Intel® On-Chip System Fabric (IOSF), Omnipath, CXL, HyperTransport, high-speed fabric, NVLink, Advanced Microcontroller Bus Architecture (AMBA) interconnect, OpenCAPI, Gen-Z, Cache Coherent Interconnect for Accelerators (CCIX), 3GPP Long Term Evolution (LTE) (4G), 3GPP 5G, and variations thereof. Data can be copied or stored to virtualized storage nodes using a protocol such as NVMe over Fabrics (NVMe-oF) or NVMe.

Processor(s) 1010 may comprise and SoC or SoP in which one or more of the components shown in dashed boxes are integrated on the SoC or SoP. These include memory controller 1022, interfaces 1012 and 1014, and a GPU 1041. Memory controller 1022 may provide signaling and logic to support one or more memory channels. In some embodiments, an SoC or SoP may include multiple integrated memory controllers, each with one or more memory channels.

In addition to processors with CPUs, the teaching and principles disclosed herein may be applied to Other Processing Units (collectively termed XPUs) including one or more of Graphic Processor Units (GPUs) or General Purpose GPUs (GP-GPUs), Tensor Processing Units (TPUs), Data Processing Units (DPUs), Infrastructure Processing Units (IPUs), Artificial Intelligence (AI) processors or AI inference units and/or other accelerators, FPGAs and/or other programmable logic (used for compute purposes), etc. Moreover, as used in the following claims, the term “processor” is used to generically cover CPUs and various forms of XPUs.

Processor(s) 1010 are socketed processors, also known simply as sockets. The socketed processor is installed in an LGA socket having socket pins in accordance with the embodiments herein. During manufacture, the socket pins of the LGA socket(s) are coupled to pads and/or vias formed on or in a PCB by performing a solder reflow operation or the like, where the solder in the solder balls is melted, resulting in an electrical connection between the connector pads and PCB pads and vias. The PCB includes wiring traces in various layers that are used to route signals, ground, and supply voltage(s) to various components on the platform. As applied to memory, these may include DIMM connectors that are mounted to the PCB (which may be considered a motherboard, main board, etc.) configured to receive a memory DIMM employing one or more of the memory technologies discussed above. The signals routed from a processor/SoC/SoP include memory channel signals, in addition to various types of I/O signals.

While various embodiments described herein use the term System-on-a-Chip or System-on-Chip (“SoC”) to describe a device or system having a processor and associated circuitry (e.g., I/O circuitry, power delivery circuitry, memory circuitry, etc.) integrated monolithically into a single Integrated Circuit (“IC”) die, or chip, the present disclosure is not limited in that respect. For example, in various embodiments of the present disclosure, a device or system can have one or more processors (e.g., one or more processor cores) and associated circuitry (e.g., I/O circuitry, power delivery circuitry, etc.) arranged in a disaggregated collection of discrete dies, tiles and/or chiplets (e.g., one or more discrete processor core die arranged adjacent to one or more other die such as memory die, I/O die, etc.). In such disaggregated devices and systems the various dies, tiles and/or chiplets can be physically and electrically coupled together by a package structure including, for example, various packaging substrates, interposers, active interposers, photonic interposers, interconnect bridges and the like. The disaggregated collection of discrete dies, tiles, and/or chiplets can also be part of a System-on-Package (“SoP”).

Although some embodiments have been described in reference to particular implementations, other implementations are possible according to some embodiments. Additionally, the arrangement and/or order of elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other. Additionally, “communicatively coupled” means that two or more elements that may or may not be in direct contact with each other, are enabled to communicate with each other. For example, if component A is connected to component B, which in turn is connected to component C, component A may be communicatively coupled to component C using component B as an intermediary component.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

As used herein, a list of items joined by the term “at least one of” can mean any combination of the listed terms. For example, the phrase “at least one of A, B or C” can mean A; B; C; A and B; A and C; B and C; or A, B and C.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the drawings. Rather, the scope of the invention is to be determined entirely by the following claims, which are to be construed in accordance with established doctrines of claim interpretation.

What is claimed is:

1. A socket pin comprising:
a body coupled to a base;
a cantilevered spring member coupled to an upper portion of the body having a lower lever directed in a first direction coupled to an upper lever directed in a second direction to form a nose, the cantilevered spring member folding back on itself; and
a shunting lever, coupled to the upper portion of the body.

2. The socket pin of claim 1, wherein when the socket pin is compressed, a portion of the shunting lever is in contact with a portion of the cantilevered spring member.

3. The socket pin of claim 2, wherein the cantilevered spring member further includes a tail coupled to the upper lever having a free end generally extending downward, wherein when the socket pin is compressed, a portion of the shunting lever is in contact with a portion of the tail of the cantilevered member.

4. The socket pin of claim 1, wherein the cantilevered spring member is coupled to the upper portion of the body on a right or left side of the body and the shunting lever is coupled to the body on an opposite side of the cantilevered spring member.

5. The socket pin of claim 4, wherein when the socket pin is viewed from a top view the cantilevered spring member is shaped such that a portion of the cantilevered spring member is disposed above a portion of the shunting lever.

6. The socket pin of claim 1, further comprising left and right tabs coupled to the body.

7. The socket pin of claim 6, wherein the left arm is angled relative to the body in a first angular direction and the right arm is angled relative to the body in the second angular direction.

8. The socket pin of claim 1, wherein the body includes a face, and wherein when the socket pin is viewed from a view perpendicular to the face a portion of the face is vertically offset from the base.

9. The socket pin of claim 1, wherein the base comprises a solder ball.

10. A connector, comprising:
a connector body, having a plurality of socket pins installed in respective socket pin housings, each socket pin comprising,
a body coupled to a base;
a cantilevered spring member coupled to an upper portion of the body having a lower lever directed in a first direction coupled to an upper lever directed in a second direction to form a nose, the cantilevered spring member folding back on itself; and
a shunting lever, coupled to the upper portion of the body.

11. The connector of claim 10, wherein the connector comprises a Land Grid Array (LGA) socket and the bases of the socket pins comprise solder balls.

12. The connector of claim 10, wherein when a socket pin is compressed, a portion of the shunting lever is in contact with a portion of the cantilevered member.

13. The connector of claim 12, wherein a cantilevered spring member further includes a tail coupled to the upper lever having a free end generally extending downward, wherein when the socket pin is compressed, a portion of the shunting lever is in contact with a portion of the tail of the cantilevered member.

14. The connector of claim 10, wherein, for a socket pin, the cantilevered spring member is coupled to the upper portion of the body on a right or left side of the body and the shunting level is coupled to the body on an opposite side of the cantilevered spring member.

15. The connector of claim 14, wherein when the connector is viewed from a top view, for a pin the cantilevered spring member is shaped such that a portion of the cantilevered spring member is disposed above a portion of the shunting lever.

16. A system, comprising:
a connector, comprising a Land Grid Array (LGA) socket including,
a housing, having a plurality of socket pins installed in respective socket pin slots, each socket pin comprising,
a body coupled to a base comprising a solder ball;
a cantilevered spring member coupled to an upper portion of the body having a lower lever directed in a first direction coupled to an upper lever directed in a second direction to form a nose, the cantilevered spring member folding back on itself; and
a shunting lever, coupled to the upper portion of the body;
a processor, installed in the socket, having a plurality of contact pads in contact with the plurality of socket pins; and
a printed circuit board (PCB) to which the LGA socket is mounted via the solder balls.

17. The system of claim 16, wherein a cantilevered spring member further includes a tail coupled to the upper lever having a free end generally extending downward, wherein a portion of the shunting lever is in contact with a portion of the tail of the cantilevered member.

18. The system of claim 16, further comprising one or more Dual Inline Memory Module (DIMM) connectors, mounted to the PCB, having or configured to have a respective DIMM memory device installed therein, wherein the PCB includes wiring traces and vias routing signals from a portion of the socket pins to pins on the one or more DIMM connectors.

19. The system of claim 18. wherein the DIMM memory devices comprise double data rate 5^{th} generation (DDR5) or double data rate 6^{th} generation (DDR6) DIMMs.

20. The system of claim 16. wherein the processor comprises a System-on-Chip (SoC) or a System-on-Package (SoP).
